(19) United States
(12) Patent Application Publication
(10) Pub. No.: US 2024/0321679 A1
(43) Pub. Date: Sep. 26, 2024

(54) HEAT DISSIPATION STRUCTURE AND SEMICONDUCTOR PACKAGE INCLUDING THE SAME

(71) Applicant: Samsung Electronics Co., Ltd., Suwon-si (KR)

(72) Inventors: Youngjoon KOH, Suwon-si (KR); Jaechoon KIM, Suwon-si (KR)

(73) Assignee: Samsung Electronics Co., Ltd., Suwon-si (KR)

(21) Appl. No.: 18/505,412

(22) Filed: Nov. 9, 2023

(30) Foreign Application Priority Data
Mar. 24, 2023 (KR) 10-2023-0039169
May 11, 2023 (KR) 10-2023-0061350

(51) Int. Cl. H01L 23/427; H01L 25/18; H10B 80/00

(52) U.S. Cl. CPC H01L 23/427; H01L 25/18; H10B 80/00; H01L 24/05; H01L 24/06; H01L 24/13; H01L 24/16; H01L 24/32; H01L 24/73; H01L 2224/05124; H01L 2224/05144; H01L 2224/05147; H01L 2224/05155; H01L 2224/05169; H01L 2224/05184; H01L 2224/0557; H01L 2224/06181; H01L 2224/13111; H01L 2224/13124; H01L 2224/13139; H01L 2224/13144; H01L 2224/13147; H01L 2224/16225; H01L 2224/32245; H01L 2224/73253; H01L 2924/1431; H01L 2924/1436; H01L 2924/1437; H01L 2924/1438; H01L 2924/1441; H01L 2924/1443

(57) ABSTRACT

A heat dissipation structure may include a heat dissipation chamber including a lower wall, an upper wall on the lower wall, and a plurality of sidewalls extending between the lower wall and the upper wall, the heat dissipation chamber providing an inner space for a working fluid to flow therein; and a wick structure on an inner surface of the heat dissipation chamber. The wick structure may be configured to guide the working fluid in a liquid state. The heat dissipation chamber may be configured to change its shape according to a temperature.

### CROSS-REFERENCE TO RELATED APPLICATIONS

This application is based on and claims priority under 35 U.S.C. § 119 to Korean Patent Application Nos. 10-2023-0039169, filed on Mar. 24, 2023, and 10-2023-0061350, filed on May 11, 2023, in the Korean Intellectual Property Office, the disclosures of each of which are incorporated by reference herein in their entirety.

### BACKGROUND

Inventive concepts relate to a heat dissipation structure and a semiconductor package including the same.

Recently, various semiconductor devices have been packaged in a single semiconductor package, and the semiconductor devices may be electrically connected to one another to operate as a single system. However, excessive heat may be generated when the semiconductor devices operate, and the performance of the semiconductor package may deteriorate due to such excessive heat.

### SUMMARY

Inventive concepts provide a heat dissipation structure with improved heat dissipation characteristics.

Inventive concepts also provide a semiconductor package with improved heat dissipation characteristics.

According to an embodiment of inventive concepts, a heat dissipation structure may include a heat dissipation chamber including a lower wall, an upper wall on the lower wall, and a plurality of sidewalls extending between the lower wall and the upper wall, the heat dissipation chamber providing an inner space for a working fluid to flow therein; and a wick structure on an inner surface of the heat dissipation chamber, the wick structure being configured to guide the working fluid in a liquid state. The heat dissipation chamber may be configured to change its shape according to a temperature.

According to an embodiment of inventive concepts, a semiconductor package may include a substrate; a semiconductor device on the substrate; and a heat dissipation structure on the semiconductor device, the heat dissipation structure including a heat dissipation chamber on the semiconductor device, the heat dissipation chamber providing an inner space for a working fluid to flow therein. A first shape of the heat dissipation structure at a first temperature may differ from a second shape of the heat dissipation structure at a second temperature. The first temperature and the second temperature may be different from each other.

According to an embodiment of inventive concepts, a semiconductor package may include a package substrate; an interposer substrate on the package substrate; a first semiconductor device on the interposer substrate; a second semiconductor device spaced apart from the first semiconductor device in a horizontal direction, the second semiconductor device on the interposer substrate; and a heat dissipation structure on the first semiconductor device and the second semiconductor device. The heat dissipation structure may include a heat dissipation chamber and a wick structure. The heat dissipation chamber may include a lower wall on the first semiconductor device, an upper wall on the lower wall, and a plurality of sidewalls extending between the lower wall and the upper wall to provide an inner space for a working fluid to flow therein. The wick structure may be on an inner surface of the heat dissipation chamber. The wick structure may be configured to guide the working fluid in a liquid state. A first shape of the heat dissipation structure at a first temperature may differ from a second shape of the heat dissipation structure at a second temperature. The second temperature may be higher than the first temperature, and a surface area of the heat dissipation structure at the second temperature may be greater than a surface area of the heat dissipation structure at the first temperature.

### BRIEF DESCRIPTION OF THE DRAWINGS

Embodiments of inventive concepts will be more clearly understood from the following detailed description taken in conjunction with the accompanying drawings in which:

FIG. 1 is a cross-sectional view of a semiconductor package according to an embodiment;

FIG. 2 is a perspective view of an upper wall at a first temperature according to an embodiment;

FIG. 3 is a perspective view of an upper wall at a second temperature according to an embodiment;

FIG. 4 is a perspective view of an upper wall at a second temperature according to an embodiment;

FIG. 5 is a perspective view of an upper wall at a second temperature according to an embodiment; and

FIGS. 6 and 7 are cross-sectional views of a method of manufacturing a semiconductor package, according to an embodiment.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

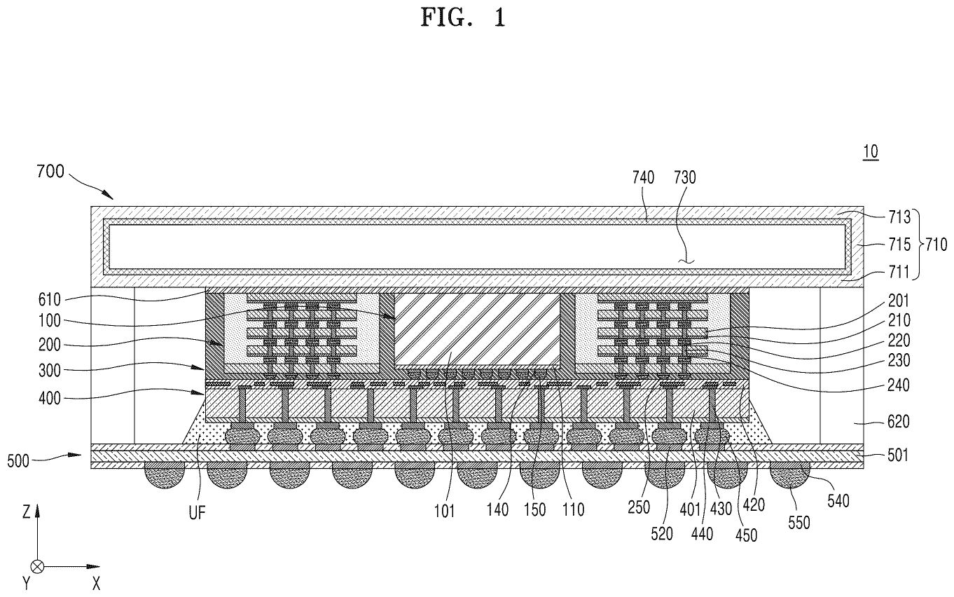

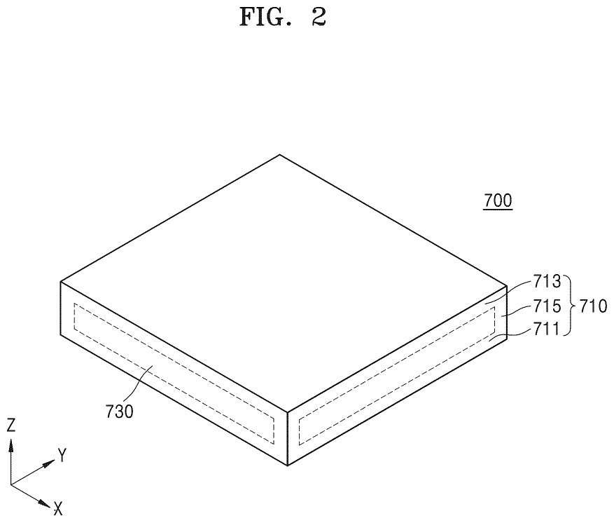

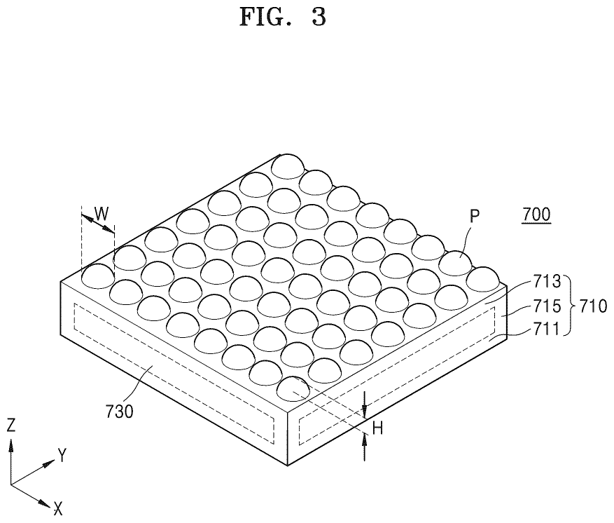

FIG. 1 is a cross-sectional view of a semiconductor package according to an embodiment. FIG. 2 is a perspective view of an upper wall at a first temperature according to an embodiment, and FIG. 3 is a perspective view of an upper wall at a second temperature according to an embodiment.

Referring to FIGS. 1 to 3, a semiconductor package 10 may include a first semiconductor device 100, a second semiconductor device 200, a molding layer 300, an interposer substrate 400, a package substrate 500, and a heat dissipation structure 700.

The semiconductor package 10 may include the first semiconductor device 100 and the second semiconductor device 200 that perform different functions. The semiconductor package 10 may include one or more first semiconductor devices 100 and one or more second semiconductor devices 200. The first semiconductor device 100 and the second semiconductor device 200 may be arranged side-by-side in a first horizontal direction (e.g., X direction) and/or a second horizontal direction (e.g., Y direction). The first semiconductor device 100 and the second semiconductor device 200 may be electrically connected to each other through the interposer substrate 400. For example, the second semiconductor devices 200 may be arranged on one side and another side of one first semiconductor device 100. However, the numbers and the arrangements of semiconductor devices shown in FIG. 1 are only an example, and the numbers and arrangements of semiconductor devices may be changed as needed.

In the present specification, the horizontal direction (X direction and/or Y direction) may refer to a direction parallel to a main surface of the package substrate 500 and the vertical direction (Z direction) may refer to a direction perpendicular to the horizontal direction (X direction and/or Y direction).

According to embodiments, the power consumption of the first semiconductor device 100 may be greater than the power consumption of the second semiconductor device 200, and the amount of heat generated during operation of the first semiconductor device 100 may be greater than the amount of heat generated during operation of the second semiconductor device 200.

The first semiconductor device 100 may include a logic chip. The logic chip may include a plurality of logic elements (not shown) therein. A logic element may refer to an element that includes, for example, logic circuits like an AND, an OR, a NOT, and a flip-flop, and performs various signal processing. According to some embodiments, the logic element may be an element performing signal processing like analog signal processing, analog-to-digital conversion, and controlling.

According to some embodiments, the first semiconductor device 100 may be implemented as a microprocessor, a graphics processor, a signal processor, a network processor, a chipset, an audio codec, a video codec, an application processor, a system-on-chip, etc.

The second semiconductor device 200 may include a memory chip, e.g., a volatile memory chip and/or a non-volatile memory chip. The volatile memory chip may be, for example, a dynamic random access memory (DRAM) chip, a static RAM (SRAM) chip, or a thyristor RAM (TRAM) chip. The non-volatile memory chip may be, for example, a flash memory chip, a magnetic RAM (MRAM) chip, a spin-transfer torque MRAM (STT-MRAM) chip, a ferroelectric RAM (FRAM) chip, a phase change RAM (PRAM) chip, or a resistive RAM (RRAM) chip.

According to some embodiments, the second semiconductor device 200 may include a memory chiplet including a plurality of memory chips capable of merging data with each other. Also, the second semiconductor device 200 may include a high bandwidth memory (HBM) chip.

Components constituting the first semiconductor device 100 and the second semiconductor device 200 are described below in detail.

The first semiconductor device 100 may include a first semiconductor substrate 101, a first semiconductor wiring layer 110, and a first connection pad 140.

The first semiconductor device 100 may include a single slice, and the single slice may include the first semiconductor substrate 101. The first semiconductor substrate 101 is a wafer and may have an active surface and an inactive surface facing each other. Here, the inactive surface of the first semiconductor substrate 101 may be the top surface of the first semiconductor device 100 exposed from the molding layer 300. The top surface of the first semiconductor substrate 101 may be on a plane perpendicular to the vertical direction (e.g., Z direction).

The first semiconductor substrate 101 may be, for example, a silicon (Si) wafer including crystalline Si, polycrystalline Si, or amorphous Si. Alternatively, the first semiconductor substrate 101 may include a semiconductor element like germanium (Ge) or a compound semiconductor like silicon carbide (SiC), gallium arsenide (GaAs), indium arsenide (InAs), and indium phosphide (InP).

In addition, the first semiconductor substrate 101 may have a silicon-on-insulator (SOI) structure. For example, the first semiconductor substrate 101 may include a buried oxide (BOX) layer. According to some embodiments, the first semiconductor substrate 101 may include a conductive region, e.g., a well doped with an impurity or a structure doped with an impurity. Also, the first semiconductor substrate 101 may have various device isolation structures like a shallow trench isolation (STI) structure.

The first semiconductor wiring layer 110 may be disposed on the active surface of the first semiconductor substrate 101 and may be electrically connected to the first connection pad 140 on the first semiconductor wiring layer 110. The first semiconductor wiring layer 110 may be electrically connected to the first connection member 150 through the first connection pad 140. The first connection pad 140 may include, for example, at least one from among aluminum (Al), copper (Cu), nickel (Ni), tungsten (W), platinum (Pt), and gold (Au).

The first connection member 150 may be disposed to electrically interconnect the first semiconductor device 100 to the interposer substrate 400. For example, the first connection member 150 may be a solder ball attached to the first connection pad 140. A material constituting the solder ball may include at least one of gold (Au), silver (Ag), copper (Cu), tin (Sn), and aluminum (Al). According to some embodiments, the solder ball may be connected to the first connection pad 140 through any one of a thermo-compression connection and an ultrasonic connection or through a thermo-sonic connection, which is a combination of the thermal compression connection and the ultrasonic connection.

Through the first connection member 150, the first semiconductor device 100 may be provided at least one of a control signal, a power signal, and a ground signal for operation of the first semiconductor device 100 from the outside, may be provided a data signal to be input to the first semiconductor device 100 from the outside, or may provide a data signal of the first semiconductor device 100 to the outside.

The second semiconductor device 200 may include a second semiconductor substrate 201, a second semiconductor wiring layer 210, a second upper connection pad 220, a second via electrode 230, and a second lower connection pad 240.

The second semiconductor device 200 may include a plurality of slices, and the plurality of slices may each include the second semiconductor substrate 201. A plurality of second semiconductor substrates 201 may constitute a chip stack and be stacked in the vertical direction (Z direction). For convenience of explanation, the uppermost second semiconductor substrate 201 from among the plurality of second semiconductor substrates 201 may be referred to as an uppermost second semiconductor substrate 201.

For example, the plurality of second semiconductor substrates 201 may be substantially the same as one another. According to another embodiment, except for the uppermost second semiconductor substrate 201, the other second semiconductor substrates 201 may be substantially identical to one another. The thickness of the uppermost second semiconductor substrate 201 may be greater than the thickness of each of the other second semiconductor substrates 201. The second semiconductor device 200 may have a stacked structure in which each slice operates as a memory chip and data may be merged therebetween.

The plurality of second semiconductor substrates 201 may each have an active surface and an inactive surface facing each other. Here, the inactive surface of the uppermost second semiconductor substrate 201 may be the top surface of the second semiconductor device 200 exposed from the molding layer 300. From among the plurality of second semiconductor substrates 201, the second semiconductor substrates 201 other than the uppermost second semiconductor substrate 201 may include second via electrodes 230. The second via electrode 230 may be, for example, a through silicon via (TSV). According to another embodiment, the uppermost second semiconductor substrate 201 may include second via electrodes 230.

The second upper connection pad 220 may be connected to the upper side of the second via electrode 230, and the second lower connection pad 240 may be connected to the lower side of the second via electrode 230. Also, the second lower connection pad 240 may be electrically connected to the second semiconductor wiring layer 210 on the active surface of the second semiconductor substrate 201. The second semiconductor wiring layer 210 may be electrically connected to the second connection member 250 through the second lower connection pad 240.

The second connection member 250 may be a solder ball attached to the second lower connection pad 240. The second connection member 250 contacting the lowermost second semiconductor substrate 201 from among the plurality of second semiconductor substrates 201 may electrically interconnect the second semiconductor device 200 to the interposer substrate 400.

Through the second connection member 250, the second semiconductor device 200 may be provided at least one of a control signal, a power signal, and a ground signal for operation of the second semiconductor device 200 from the outside, may be provided a data signal to be input to the second semiconductor device 200 from the outside, or may provide a data signal of the second semiconductor device 200 to the outside.

The molding layer 300 may be formed to surround the first semiconductor device 100 and the second semiconductor device 200. In detail, the molding layer 300 may extend along side surfaces and bottom surfaces of the first semiconductor device 100 and the second semiconductor device 200 and cover the side surfaces and the bottom surfaces of the first semiconductor device 100 and the second semiconductor device 200. Here, the molding layer 300 may not cover the top surface of the first semiconductor device 100 and the top surface of the second semiconductor device 200. According to embodiments, the top surface of the molding layer 300 may be coplanar with the top surface of the first semiconductor device 100 and the top surface of the second semiconductor device 200.

The molding layer 300 may protect the first semiconductor device 100 and the second semiconductor device 200 from external influences like impact and contamination. To this end, the molding layer 300 may include an epoxy mold compound or a resin. Also, the molding layer 300 may be formed through a process like compression molding, lamination, or screen printing.

The interposer substrate 400 is disposed below the first semiconductor device 100 and the second semiconductor device 200 and may electrically connect the first semiconductor device 100 and the second semiconductor device 200 to each other. According to some embodiments, the interposer substrate 400 may include a silicon substrate 401 and may include a redistribution structure 420 disposed on the silicon substrate 401. Also, the interposer substrate 400 may include a via electrode 430 electrically connected to the redistribution structure 420 and penetrating through the silicon substrate 401, a connection pad 440 disposed below the silicon substrate 401 and electrically connected to the via electrode 430, and an internal connection terminal 450 attached to the connection pad 440.

The package substrate 500 may be disposed below the interposer substrate 400. The package substrate 500 may be formed based on a printed circuit board, a wafer substrate, a ceramic substrate, a glass substrate, etc. According to embodiments, the package substrate 500 may be a printed circuit board. The package substrate 500 may include a bump pad 540 disposed on the bottom surface of a body 501 and an external connection terminal 550 attached to the bottom surface of the bump pad 540. The semiconductor package 10 may be electrically connected to a main board or a system board of an external electronic device on which the semiconductor package 10 is mounted through the external connection terminal 550.

An underfill layer UF may be disposed between the interposer substrate 400 and the package substrate 500. The underfill layer UF may fill a gap between the interposer substrate 400 and the package substrate 500 and may surround the internal connection terminal 450. The underfill layer UF may include, for example, an epoxy resin. According to some embodiments, a non-conductive film (NCF) may be formed instead of the underfill layer UF.

The heat dissipation structure 700 may be disposed on the first semiconductor device 100 and the second semiconductor device 200 and may be thermally coupled to the first semiconductor device 100 and the second semiconductor device 200. The heat dissipation structure 700 may be attached to the first semiconductor device 100 and the second semiconductor device 200 through a thermally conductive adhesive layer 610 applied on top surfaces of the first semiconductor device 100 and the second semiconductor device 200. The thermally conductive adhesive layer 610 may conformally extend along the top surfaces of the first semiconductor device 100 and the second semiconductor device 200. The thermally conductive adhesive layer 610 may be thermally conductive and electrically non-conductive. For example, the thermally conductive adhesive layer 610 may include a resin layer containing various fillers. The thermally conductive adhesive layer 610 may include a thermal interfacial material (TIM) layer.

The heat dissipation structure 700 is thermally coupled to the first semiconductor device 100 and the second semiconductor device 200 and may be configured to cool the first semiconductor device 100 and the second semiconductor device 200 through immersion cooling. The heat dissipation structure 700 may be configured to perform cooling of a heat source through a phase change of a working fluid. In the heat dissipation structure 700, the working fluid in a liquid state is evaporated through heat exchange with a heat source and phase-changed to a gaseous state, and the working fluid in the gaseous state is condensed through heat exchange with a cold wall in the heat dissipation structure 700 and phase-changed to the liquid state. Through the phase change of the working fluid, heat from the heat source (e.g., the first semiconductor device 100 and the second semiconductor device 200) may be released to the outside. The working fluid may be a coolant configured to change phase within the operating temperature range of the semiconductor package 10. The working fluid may include, for example, water, ethylene glycol, silicone oil, mineral oil, liquid TEFLON® (e.g., a polytetrafluoroethylene-based composition), or a mixture thereof.

The heat dissipation structure 700 may include a heat dissipation chamber 710 providing an inner space 730 through which the working fluid flows and a wick structure 740 provided in the heat dissipation chamber 710.

The heat dissipation chamber 710 may include a lower wall 711, an upper wall 713 on the lower wall 711, and sidewalls 715 extending between the lower wall 711 and the upper wall 713. The lower wall 711 and the upper wall 713 may each have a flat plate-like shape and may be parallel to each other. The lower wall 711 may be attached to the first semiconductor device 100 and the second semiconductor device 200 through the thermally conductive adhesive layer 610. The lower wall 711 and the sidewalls 715 may each include a metal like copper (Cu), aluminum (Al), or stainless steel (SUS). Description of the upper wall 713 will be given later.

The planar area of the heat dissipation chamber 710 may be greater than the planar area of the interposer substrate 400. The center portion of the heat dissipation chamber 710 may vertically overlap the interposer substrate 400, and the outer portion of the heat dissipation chamber 710 may protrude outward from the interposer substrate 400. The outer portion of the heat dissipation chamber 710 may be supported by a support structure 620 attached to an outer portion of the package substrate 500. The support structure 620 may be attached onto the package substrate 500 through an adhesive material layer. A material constituting the support structure 620 may include a metal like copper (Cu), aluminum (Al), or stainless steel (SUS). According to embodiments, the support structure 620 may be integrated with the heat dissipation chamber 710, and the support structure 620 and the heat dissipation chamber 710 may include the same material.

In the heat dissipation structure 700, the lower wall 711 of the heat dissipation chamber 710 in contact with a heat source (e.g., the first semiconductor device 100 and the second semiconductor device 200) may be an evaporator where the working fluid in the liquid state is evaporated, and the upper wall 713 and the sidewalls 715 of the heat dissipation chamber 710 exposed to external air (e.g., the air outside the heat dissipation structure 700) may be a condenser where the working fluid in the gaseous state is condensed. When the lower wall 711 is heated by a heat source (e.g., the first semiconductor device 100 and the second semiconductor device 200), a space adjacent to the lower wall 711 has relatively high pressure, and thus, a pressure gradient is formed inside the heat dissipation chamber 710. According to the pressure gradient inside the heat dissipation chamber 710, the working fluid in the gaseous state flows in a direction from the lower wall 711 toward the upper wall 713 or a direction from a region of the lower wall 711 overlapping the heat source to the sidewalls 715. The heat source may be cooled in the process of evaporating the working fluid in the liquid state, and heat may be released to the external air in the process of condensing the working fluid in the gaseous state.

The shape of the upper wall 713 may vary according to the change in temperature. The surface area of the upper wall 713 at a first temperature may be less than the surface area of the upper wall 713 at a second temperature that is higher than the first temperature. For example, as shown in FIG. 2, the surface of the upper wall 713 may be flat at the first temperature. For example, as shown in FIG. 3, at the second temperature that is different from the first temperature, the upper wall 713 may include a plurality of patterns P having a concavo-convex shape. For example, the plurality of patterns P may each have a hemispherical shape. For example, the plurality of patterns P may each have a vertical cross-section having a partially circular (e.g., semicircular) shape. The surface roughness of the top surface of the upper wall 713 at the second temperature may be greater than the surface roughness of the top surface of the upper wall 713 at the first temperature. For example, the curvature of the plurality of patterns P of the upper wall 713 at the second temperature may be greater than the curvature of the top surface of the upper wall 713 at the first temperature.

The plurality of patterns P may each have a horizontal direction (X direction and/or Y direction) width W from about 1 micrometer to about 500 micrometers. Also, the plurality of patterns P may each have a height H from about 1 micrometer to about 500 micrometers. For example, the plurality of patterns P may be arranged in rows and columns in a matrix-like shape on the top surface of the upper wall 713. According to another embodiment, the plurality of patterns P may be arranged in a honeycomb-like shape on the top surface of the upper wall 713. According to another embodiment, the plurality of patterns P may be irregularly arranged on the top surface of the upper wall 713. For example, the shape of the vertical cross-section of each of the plurality of patterns P may be a semicircle and/or a part of an ellipse.

For example, the upper wall 713 may include a shape memory alloy. The shape memory alloy may be an alloy that restores to a remembered shape at a particular temperature. The shape memory alloy may have a first shape and a second shape that are different from each other. When a general metal is deformed (e.g., from a first shape to a second shape), bonds between atoms in the metal may change. Therefore, a general metal may be irreversibly deformed into either a first shape or a second shape. However, when a shape memory alloy is deformed (e.g., from a first shape to a second shape), bonds between atoms in metals may be maintained. Therefore, a shape memory alloy may be reversibly deformed into the first shape and the second shape. The upper wall 713 may include, for example, a nickel-titanium (Ni-Ti) alloy, a copper-zinc-aluminum (Cu-Zn-Al) alloy, and/or a copper-aluminum-nickel (Cu-Al-Ni) alloy. For example, the upper wall 713 may include a material that is different from those of the lower wall 711 and the plurality of sidewalls 715.

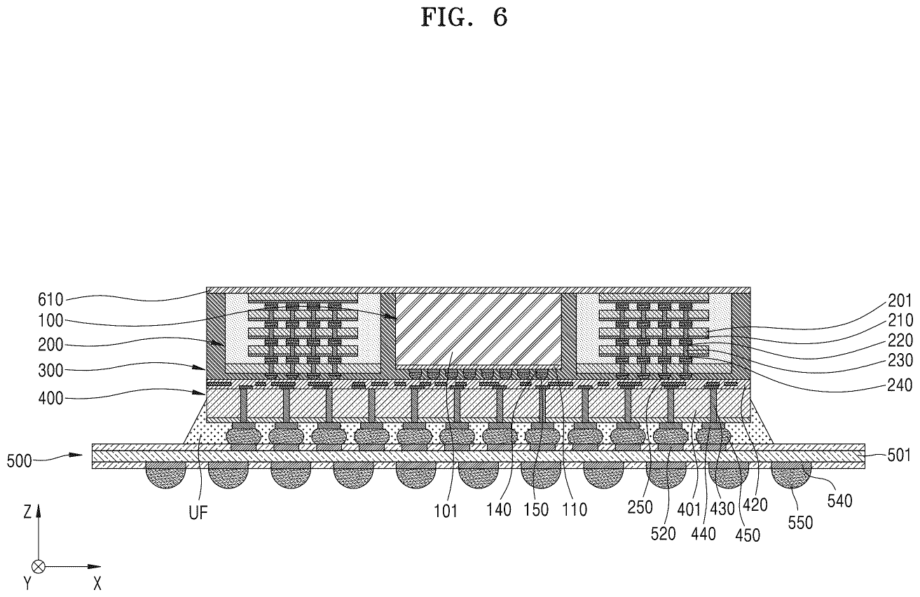

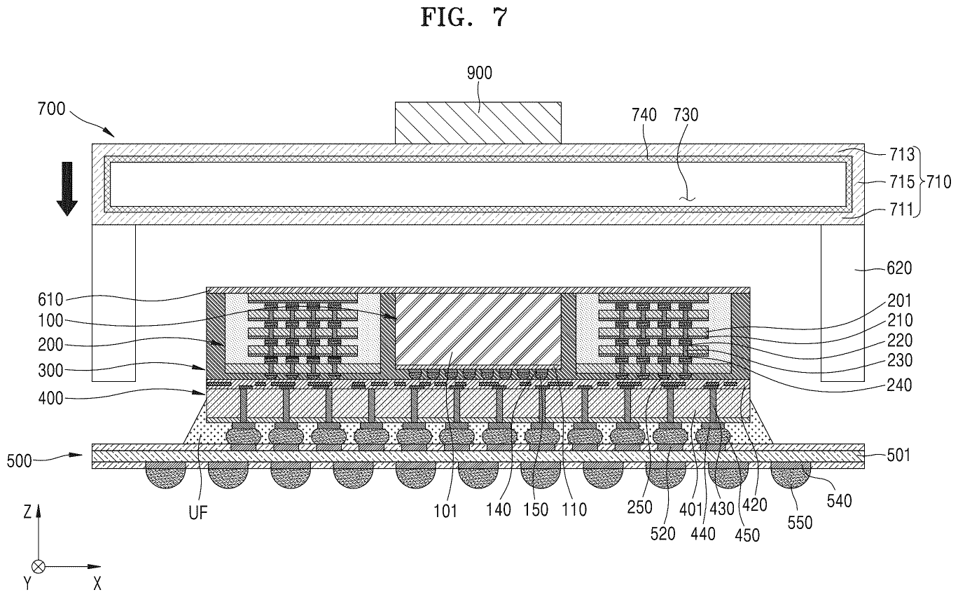

For example, the first temperature may be a process temperature of the upper wall 713 in a process of manufacturing the semiconductor package 10, and the second temperature may be a temperature of the upper wall 713 when the first semiconductor device 100 or the second semiconductor device 200 operates. For example, the first temperature may be a temperature of the upper wall 713 when the first semiconductor device 100 and the second semiconductor device 200 do not operate. For example, to manufacture the semiconductor package 10, a picker (900 of FIG. 7) may adsorb the heat dissipation structure 700 and place the heat dissipation structure 700 on the first semiconductor device 100 and the second semiconductor device 200. When the picker (900 of FIG. 7) adsorbs the heat dissipation structure 700, the picker (900 of FIG. 7) may adsorb the top surface of the upper wall 713. Therefore, when the top surface of the upper wall 713 is flat, the picker (900 of FIG. 7) may easily adsorb the heat dissipation structure 700. A method of manufacturing the semiconductor package 10 is described in more detail with reference to FIGS. 6 and 7.

A critical temperature of the shape memory alloy constituting the upper wall 713 may be located between the first temperature and the second temperature. Around the critical temperature, the shape of the shape memory alloy may be changed reversibly. For example, the first temperature may be from about 15° C. to about 30° C. and the second temperature may be from about 40° C. to about 80° C. For example, the critical temperature of the shape memory alloy constituting the upper wall 713 may be from about 30° C. to about 40° C.

At the second temperature, as the surface area of the top surface of the upper wall 713 increases, the cooling efficiency of the upper wall 713 may increase. Therefore, heat generated by the semiconductor package 10 may be easily discharged to the outside of the semiconductor package 10.

The wick structure 740 may define the inner space 730 in which the working fluid flows. For example, the wick structure 740 may surround the inner space 730. The wick structure 740 may extend along inner walls of the heat dissipation chamber 710. The wick structure 740 may be attached to at least one of the surface of the lower wall 711, the surface of the upper wall 713, and the surfaces of the sidewalls 715. According to some embodiments, the wick structure 740 may be attached to all of the surface of the lower wall 711, the surface of the upper wall 713, and the surfaces of the sidewalls 715. According to other embodiments, the wick structure 740 may only be attached to some of the surface of the lower wall 711, the surface of the upper wall 713, and the surfaces of the sidewalls 715. For example, the wick structure 740 may be formed on the surface of the lower wall 711, and the wick structure 740 may not be formed on the surface of the upper wall 713 and the surfaces of the sidewalls 715. The wick structure 740 may generate capillary force to move the working fluid in the liquid state toward a heat source. The wick structure 740 is a structure for generating capillary force and may include, for example, a groove pattern. The wick structure 740 may include a metal or metal powder sintered body. For example, the wick structure 740 may include copper (Cu) or aluminum (Al). Within the heat dissipation chamber 710, the working fluid in the liquid state may move toward the heat source by gravity or capillary force of the wick structure 740.

Unlike the upper wall 713, shapes of the lower wall 711, the plurality of sidewalls 715, and the wick structure 740 may not be changed according to a change in temperature. In other words, the lower wall 711, the plurality of sidewalls 715, and the wick structure 740 may each have the same shape at the first temperature and the second temperature. According to another embodiment, the shapes of the lower wall 711, the plurality of sidewalls 715, and/or the wick structure 740 may be changed according to a change in temperature. In other words, the shape of each of the lower wall 711, the plurality of sidewalls 715, and the wick structure 740 at the first temperature may be different from the shape of each of the lower wall 711, the plurality of sidewalls 715, and the wick structure 740 at the second temperature.

The top surface of an upper wall of a heat dissipation structure of a general semiconductor package has substantially the same shape even when the temperature thereof is changed. For example, when the top surface of an upper wall has a flat shape, it is easy to adsorb the upper wall and manufacture a semiconductor package, but the capability of dissipating heat generated in the semiconductor package to the outside is relatively low. On the contrary, when the top surface of the upper wall is not flat, the capability of discharging heat generated in the semiconductor package to the outside is relatively high, but it is not easy to adsorb the upper wall to manufacture the semiconductor package.

The semiconductor package 10 of inventive concepts includes the upper wall 713 of which the shape is changed according to temperature, and thus, when the semiconductor package 10 is manufactured, the top surface of the upper wall 713 may be flat. Therefore, the semiconductor package 10 may be easily manufactured. Also, when the semiconductor package 10 operates and the temperature of the upper wall 713 increases, the shape of the upper wall 713 is changed and the surface area of the upper wall 713 increases, thereby facilitating discharge of heat generated by the semiconductor package 10 to the outside.

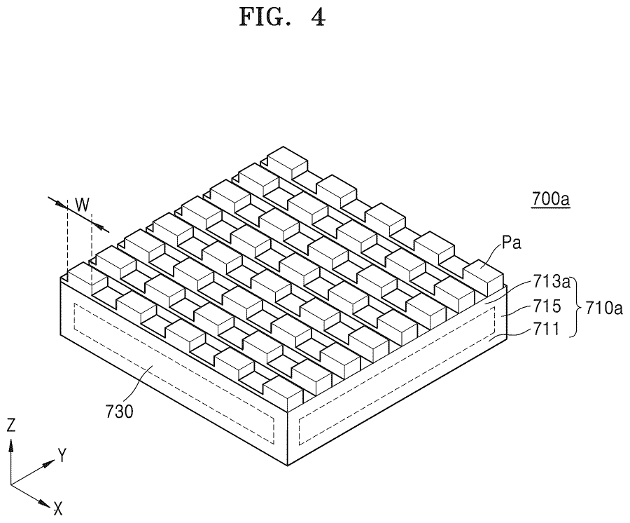

FIG. 4 is a perspective view of an upper wall at a second temperature according to an embodiment. Descriptions below are given with reference to FIGS. 1 to 3 together.

Referring to FIG. 4, the top surface of an upper wall 713a at the second temperature may have a plurality of patterns Pa having a concavo-convex shape. Compared to the top surface of the upper wall 713 at the first temperature of FIG. 2 having a flat surface, when the plurality of patterns Pa on the top surface of the upper wall 713a have a concavo-convex shape, the surface area of the top surface of the upper wall 713a may be increased. For example, the shape of the vertical cross-section of each of the plurality of patterns Pa may be a rectangle.

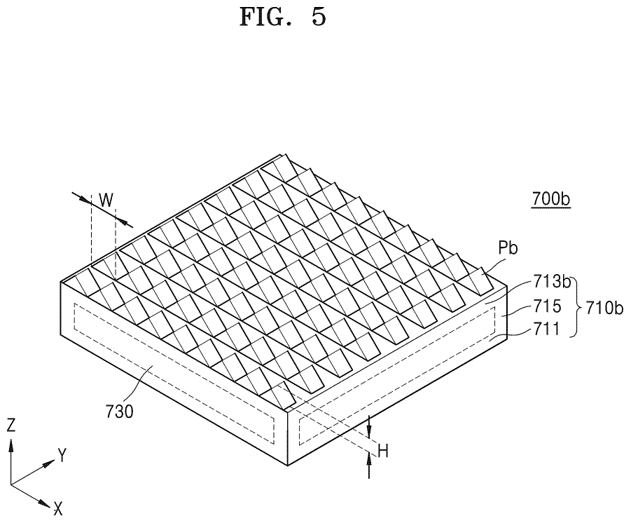

FIG. 5 is a perspective view of an upper wall at a second temperature according to an embodiment. Descriptions below are given with reference to FIGS. 1 to 3 together.

Referring to FIG. 5, the top surface of an upper wall 713b at the second temperature may have a plurality of patterns Pb having a concavo-convex shape. Compared to the top surface of the upper wall 713 at the first temperature of FIG. 2 having a flat surface, when the plurality of patterns Pa on the top surface of the upper wall 713b have a concavo-convex shape, the surface area of the top surface of the upper wall 713b may be increased. For example, the shape of the vertical cross-section of each of the plurality of patterns Pb may be a triangle.

In FIGS. 3 to 5, cases where the shapes of the vertical cross-sections of each of a plurality of patterns P, Pa, and Pb of upper walls 713, 713a, and 713b are a part of a circle, a rectangle, and a triangle have been described. However, the shapes of the vertical cross-sections of each of the plurality of patterns P, Pa, and Pb of the upper walls 713, 713a, and 713b are not limited thereto. For example, the shape of the vertical cross-section of each of the plurality of patterns P, Pa, and Pb of the upper walls 713, 713a, and 713b may be a circle, a part of an ellipse, a trapezoid, an inverted-trapezoid, a wavy shape, a polygon, and/or atypical. In other words, the plurality of patterns P, Pa, and Pb of the upper walls 713, 713a, and 713b may have any shape in which the surface areas of the top surfaces of the upper walls 713, 713a, and 713b are increased.

FIGS. 6 and 7 are cross-sectional views of a method of manufacturing a semiconductor package, according to an embodiment.

Referring to FIG. 6, the first semiconductor device 100 and the second semiconductor device 200 are mounted on the interposer substrate 400, and the molding layer 300 surrounding the first semiconductor device 100 and the second semiconductor device 200 is formed. In the formation of the molding layer 300, the molding layer 300 may expose the top surfaces of the first semiconductor device 100 and the second semiconductor device 200. According to embodiments, the top surface of the molding layer 300 may be coplanar with the top surface of the first semiconductor device 100 and the top surface of the second semiconductor device 200. The interposer substrate 400 may serve to electrically connect the first semiconductor device 100 and the second semiconductor device 200 to each other. Also, the internal connection terminal 450 may be formed under the interposer substrate 400.

Next, the interposer substrate 400 on which the first semiconductor device 100 and the second semiconductor device 200 are mounted may be disposed on the package substrate 500. The interposer substrate 400 may be disposed on the package substrate 500, such that the internal connection terminal 450 disposed under the interposer substrate 400 is electrically connected to the top surface of the package substrate 500.

After the interposer substrate 400 is disposed on the package substrate 500, the underfill layer UF may be formed between the interposer substrate 400 and the package substrate 500. The underfill layer UF may be disposed between the interposer substrate 400 and the package substrate 500 and surround the internal connection terminal 450.

Next, the thermally conductive adhesive layer 610 covering the top surfaces of the first semiconductor device 100 and the second semiconductor device 200 is formed. The thermally conductive adhesive layer 610 may cover the top surfaces of the first semiconductor device 100 and the second semiconductor device 200 and may further cover the top surface of the molding layer 300.

Referring to FIGS. 2 and 7, the heat dissipation structure 700 having the support structure 620 is prepared, and the heat dissipation structure 700 is attached onto the first semiconductor device 100 and the second semiconductor device 200. For example, the picker 900 may adsorb the heat dissipation structure 700 and attach the heat dissipation structure 700 onto the first semiconductor device 100 and the second semiconductor device 200. For example, the picker 900 may adsorb onto the upper wall 713 of the heat dissipation structure 700 and attach the heat dissipation structure 700 onto the first semiconductor device 100 and the second semiconductor device 200. For example, the picker 900 may vacuum-adsorb the heat dissipation structure 700. For the picker 900 to easily adsorb the upper wall 713 of the heat dissipation structure 700, the top surface of the upper wall 713 may have a flat shape.

The center portion of the heat dissipation structure 700 may be attached onto the first semiconductor device 100 and the second semiconductor device 200 through the thermally conductive adhesive layer 610. Also, the support structure 620 may be attached to the outer portion of the package substrate 500. For example, the support structure 620 may be attached onto the package substrate 500 through an adhesive material layer.

While inventive concepts have been particularly shown and described with reference to embodiments thereof, it will be understood that various changes in form and details may be made therein without departing from the spirit and scope of the following claims.

What is claimed is:

1. A heat dissipation structure comprising:
a heat dissipation chamber including a lower wall, an upper wall on the lower wall, and a plurality of sidewalls extending between the lower wall and the upper wall, the heat dissipation chamber providing an inner space for a working fluid to flow therein; and
a wick structure on an inner surface of the heat dissipation chamber, the wick structure being configured to guide the working fluid in a liquid state, wherein
the heat dissipation chamber is configured to change its shape according to a temperature.

2. The heat dissipation structure of claim 1, wherein
a surface area of a top surface of the heat dissipation chamber at a first temperature is less than a surface area of the top surface of the heat dissipation chamber at a second temperature, and
the second temperature is higher than the first temperature.

3. The heat dissipation structure of claim 2, wherein,
at the first temperature, the top surface of the heat dissipation chamber has a flat shape, and,
at the second temperature, the top surface of the heat dissipation chamber has a plurality of patterns having a concavo-convex shape.

4. The heat dissipation structure of claim 3, wherein the plurality of patterns are arranged in rows and columns in a matrix-like shape on the top surface of the heat dissipation chamber.

5. The heat dissipation structure of claim 3, wherein a shape of a vertical cross-section of each of the plurality of patterns comprises at least one of a semicircle, a rectangle, and a triangle.

6. The heat dissipation structure of claim 1, wherein the shape of the heat dissipation chamber changes reversibly according to the temperature.

7. The heat dissipation structure of claim 1, wherein the heat dissipation chamber comprises a shape memory alloy.

8. The heat dissipation structure of claim 1, wherein the heat dissipation chamber comprises at least one of a nickel-titanium (Ni-Ti) alloy, a copper-zinc-aluminum (Cu-Zn-Al) alloy, and a copper-aluminum-nickel (Cu-Al-Ni) alloy.

9. A semiconductor package comprising:
a substrate;
a semiconductor device on the substrate; and
a heat dissipation structure on the semiconductor device, the heat dissipation structure including a heat dissipation chamber on the semiconductor device, the heat dissipation chamber providing an inner space for a working fluid to flow therein, wherein
a first shape of the heat dissipation structure at a first temperature differs from a second shape of the heat dissipation structure at a second temperature, and
the first temperature and the second temperature are different from each other.

10. The semiconductor package of claim 9, wherein
the heat dissipation chamber comprises a lower wall on the semiconductor device, an upper wall on the lower wall, and a plurality of sidewalls extending between the lower wall and the upper wall, and
a shape of the upper wall is configured to change according to a temperature.

11. The semiconductor package of claim 9, wherein
the first temperature is a temperature of the heat dissipation structure if the semiconductor device is not operating, and
the second temperature is a temperature of the heat dissipation structure if the semiconductor device is operating.

12. The semiconductor package of claim 9, further comprising
a wick structure on an inner surface of the heat dissipation chamber, wherein
the wick structure is configured to guide the working fluid in a liquid state, and
the wick structure has a same shape at both the first temperature and the second temperature.

13. The semiconductor package of claim 9, wherein a shape of the heat dissipation structure is configured to change at a critical temperature between the first temperature and the second temperature.

14. The semiconductor package of claim 9, wherein
the first temperature is from 0° C. to 30° C., and
the second temperature is from 40° C. to 80° C.

15. A semiconductor package comprising:
a package substrate;
an interposer substrate on the package substrate;
a first semiconductor device on the interposer substrate;
a second semiconductor device spaced apart from the first semiconductor device in a horizontal direction, the second semiconductor device on the interposer substrate; and
a heat dissipation structure on the first semiconductor device and the second semiconductor device, wherein
the heat dissipation structure includes a heat dissipation chamber and a wick structure,
the heat dissipation chamber includes a lower wall on the first semiconductor device, an upper wall on the lower wall, and a plurality of sidewalls extending between the lower wall and the upper wall to provide an inner space for a working fluid to flow therein,
the wick structure is on an inner surface of the heat dissipation chamber,
the wick structure is configured to guide the working fluid in a liquid state,
a first shape of the heat dissipation structure at a first temperature differs from a second shape of the heat dissipation structure at a second temperature,
the second temperature is higher than the first temperature, and
a surface area of the heat dissipation structure at the second temperature is greater than a surface area of the heat dissipation structure at the first temperature.

16. The semiconductor package of claim 15, wherein
a shape of the upper wall at the first temperature and a shape of the upper wall at the second temperature are different from each other, and
a surface area of the upper wall at the second temperature is greater than a surface area of the upper wall at the first temperature.

17. The semiconductor package of claim 15, wherein
a shape of the lower wall is the same at the first temperature and the second temperature, and
shapes of the plurality of sidewalls are the same at the first temperature and the second temperature.

18. The semiconductor package of claim 15, wherein
a surface roughness of a top surface of the heat dissipation structure at the first temperature is lower than a surface roughness of the top surface of the heat dissipation structure at the second temperature.

19. The semiconductor package of claim 15, wherein
at the second temperature, a top surface of the heat dissipation structure comprises a plurality of patterns, and
horizontal widths of the of the plurality of patterns and heights of the plurality of patterns are each from 1 micrometer to 500 micrometers.

20. The semiconductor package of claim 15, wherein a material of the upper wall comprises a is different from a material of the lower wall and a material of the plurality of sidewalls.
